(19) United States
(12) Patent Application Publication
(10) Pub. No.: US 2025/0224434 A1
(43) Pub. Date: Jul. 10, 2025

(54) AUXILIARY INSTALLATION FIXING DEVICE AND FIXING METHOD OF VEHICLE

(71) Applicants: China Automotive Technology and Research Center Co., Ltd., Tianjin (CN); Catarc Automotive Test Center (Tianjin) Co., Ltd., Tianjin (CN)

(72) Inventors: Changqing Dong, Tianjin (CN); Kongjian Qin, Tianjin (CN); Guokai Jiang, Tianjin (CN); Jiaxu Feng, Tianjin (CN); Feiyan Wu, Tianjin (CN); Zhe Tian, Tianjin (CN); Meng Zhao, Tianjin (CN); Quan Wen, Tianjin (CN); Xiucheng Li, Tianjin (CN); Zhiqiang Yang, Tianjin (CN); Miaomiao Sheng, Tianjin (CN); Guangyu Xiao, Tianjin (CN); Zhiyu Sun, Tianjin (CN); Qiwen Zhu, Tianjin (CN); Ningning He, Tianjin (CN); Guotian Ji, Tianjin (CN)

(21) Appl. No.: 18/969,047

(22) Filed: Dec. 4, 2024

(30) Foreign Application Priority Data
Jan. 10, 2024 (CN) 202410032379.8

(51) Int. Cl. G01R 29/08; G01R 29/10

(52) U.S. Cl. CPC G01R 29/0864; G01R 29/10

(57) ABSTRACT

The present disclosure provides a vehicle auxiliary installation fixing device and a fixing method, wherein the device comprises a frame body, the frame body comprises a pair of side brackets and a pair of end brackets, the pair of side brackets are parallel to each other and both extend along a first direction, the pair of end brackets are arranged along a second direction, the end brackets are arc-shaped and connected with the ends of the same ends of the pair of side brackets, and the second direction is perpendicular to the first direction; the frame body is lined with wave-absorbing material; two groups of fixing components arranged in a first direction. The device can prevent the position of the vehicle under test from moving when the rotating bracket rotates, and avoid the problem of inaccurate test result caused by the scattering of electromagnetic waves by the device itself.

### CROSS-REFERENCE TO RELATED APPLICATIONS

This application is based on and claims the benefit of priority to the Chinese patent application No. 202410032379.8 filed on Jan. 10, 2024, which is hereby incorporated by reference in its entirety into the present disclosure.

### TECHNICAL FIELD

The present disclosure generally relates to the technical field of automobile testing, more specifically, a vehicle auxiliary installation fixing device and a fixing method.

### BACKGROUND

With the continuous development of mobile communication, people's demand for vehicles is increasing. Many cars are equipped with wireless communication systems, just as mobile phones need to complete the wireless communication test before leaving the factory, the OTA test of the vehicle wireless system is also a step to ensure the performance and reliability of the vehicle communication system, which is indispensable.

Compact antenna test is one of the measurement methods of vehicle-mounted antenna, and the key to the test is to obtain the vehicle-mounted antenna pattern. The compact antenna test is to use a reflector or lens to gather the electromagnetic waves emitted by the feed, so that the spherical waves emitted by the feed are focused into plane waves, and then the vehicle-mounted antenna is tested; It is necessary to put the car on a rotating bracket during the compact antenna test. To put the car directly on the rotating bracket without fixing, it is easy to move during the rotation because the car is large and heavy, which leads to inaccurate test results.

### SUMMARY

In view of the above-mentioned defects or deficiencies in the prior art, it is desirable to provide a vehicle auxiliary installation fixing device and a fixing method to solve the above-mentioned problems.

In a first aspect, the present disclosure provides a vehicle auxiliary installation fixing device, comprising:
a frame body, which comprises a pair of side brackets and a pair of end brackets, wherein the pair of side brackets are parallel to each other and both extend along a first direction; the pair of end brackets are arranged along a second direction; and the pair of end brackets are arc-shaped and connected with the same ends of the pair of side brackets, and the second direction is perpendicular to the first direction; the frame body is lined with wave-absorbing material; and
two groups of fixing components, which are arranged along the first direction, comprising:
a connecting rod, wherein the connecting rod extends along the second direction, and both ends of the connecting rod are respectively connected with the pair of side brackets; and
a pair of supporting plates, which are arranged on the connecting rod along the second direction for supporting a pair of front wheels or a pair of rear wheels of the vehicle under test;
the pair of supporting plates are provided with limiting parts for preventing the wheels from moving;
the section of the pair of end brackets is in the shape of a water drop; the side of the end brackets far from the other end bracket is a drop-shaped tip, and the side of the end brackets close to the other end bracket is a drop-shaped round end.

In one example, the connecting rod is slidably connected with the pair of side brackets, and the sliding direction is the first direction; the pair of supporting plates is connected with the connecting rod slidably, and the sliding direction is parallel to the second direction.

In one example, the fixing component further comprising:
a first sliding seat arranged between the pair of supporting plates; the first slide seat comprises a sliding part and an installation part arranged at one side of the sliding part, wherein the sliding part is connected with the connecting rod slidably, and the sliding direction is the second direction; and
a fixing support, which comprises a supporting part and a connecting part; the connecting part is connected with the installation part slidably, and the sliding direction is a third direction which is perpendicular to the first direction and the second direction; the supporting part is arranged at one end of the connecting part far away from the connecting rod.

In one example, both ends of the supporting part are bent in the direction away from the connecting part.

In one example, the fixing component further comprising:
a strap, two ends of which are respectively connected with two ends of the connecting rod; and
a retracting device arranged at one end of the strap for adjusting the tightness of the straps.

In one example, a plurality of groups of tensioning assemblies are further arranged between the two groups of fixing components, and the tensioning assembly comprises:
a second sliding seat, which is slidably installed on the pair of side brackets, and the sliding direction is the first direction; the position of the second sliding seat can be fixed after sliding; and
a tension zipper, one end of which is connected with the second sliding seat, and the other end of which is used for connecting with the chassis of the vehicle under test.

In one example, a angle of a tip of the water drop shape is between 70° and 85°.

In one example, the connecting rod is lined with the wave-absorbing material.

According to a second aspect of the present disclosure, there is provided a vehicle auxiliary installation fixing method, which is suitable for the vehicle auxiliary installation fixing device, wherein comprising the following steps:
adjusting the positions of the connecting rod and the pair of supporting plates to be suitable for the vehicle under test, and fixing the positions of the connecting rod and the pair of supporting plates;
placing the four wheels of the vehicle under test on the corresponding supporting plates respectively;
adjusting the height of the fixing supports until it abuts against the chassis of the vehicle under test, and fixing the height of the fixing supports;
bind the vehicle under test with the strap, and tighten the strap through the retracting devices;
connect the tension zippers with the chassis of the vehicle under test to assist in fixing the vehicle.

Compared with the prior art, the beneficial effects of the present disclosure are: During the test, four wheels of the vehicle under test are placed separately on the supporting plates of the two groups of fixing components; the vehicle is supported by the supporting plates, and the wheels of the vehicle under test can be limited by matching with the limiting parts arranged on the supporting plates, so that the wheels are prevented from moving due to inertia when the rotating bracket rotates, and the situation that the test result is inaccurate due to the deviation of the vehicle under test caused by the wheel movement is prevented; By arranging the connecting rod, on the one hand, it is used to increase the stability between a pair of side brackets of the frame body, and it is also used to facilitate the installation of the supporting plates; By arranging the end brackets of the frame body in an arc shape, the scattering of electromagnetic waves by the frame body itself can be reduced compared with arranging the end brackets in a straight line shape; By lining wave-absorbing material on the whole frame body to absorb electromagnetic waves and further reduce the scattering of electromagnetic waves by the frame body itself.

### BRIEF DESCRIPTION OF DRAWINGS

Other features, objects and advantages of the present disclosure will become more apparent by reading the detailed description of non-limiting embodiments with reference to the following drawings:

FIG. 1 is a structural schematic diagram of a vehicle auxiliary installation fixing device provided in example 1;

FIG. 2 is a structural schematic diagram of the vehicle auxiliary mounting fixture shown in FIG. 1 with no wave-absorbing material lined;

FIG. 3 is an enlarged structural schematic diagram of the selected portion “A” in FIG. 2;

FIG. 4 is a structural schematic diagram of the area division of the front end and the rear end of the pair of end brackets;

FIG. 5 is a simulation result diagram of example 1;

FIG. 6 is a flowchart of the steps of a vehicle auxiliary installation fixing method provided in example 2.

### DESCRIPTIONS OF REFERENCE NUMERALS

1. Frame body; 2. Side bracket; 3. End bracket; 4. Wave-absorbing material; 5. Connecting rod; 6. Supporting plate; 7. Limiting part; 8. First sliding seat; 9. Sliding part; 10. Installation part; 11. Fixing support; 12. Supporting part; 13. Connecting part; 14. Strap; 15. Retracting device; 16. Second sliding seat; 17. Tension zipper; 18. Third sliding seat; 19. Fourth sliding seat; 20. Front end; 21. Rear end.

### DETAILED DESCRIPTION

The present disclosure will be described in detail with reference to its embodiments, but it should be understood that the present disclosure is explained by the embodiments and not restricted to such embodiments In addition, for the convenience of description, only the parts related to the present disclosure are shown in the drawings.

It should be noted that the embodiments and the features in them in the present disclosure can be combined with each other if there is no conflict. The present disclosure will be described in detail with reference to the attached drawings and examples.

The compact antenna test is usually carried out in a microwave anechoic chamber. The equipment required for the test mainly includes a reflector, a feed and a rotating bracket. The reflector is arranged towards the rotating bracket, and the feed is arranged between the reflector and the rotating bracket. The test principle is that the feed emits spherical electromagnetic waves, and the spherical electromagnetic waves are emitted and gathered by the reflector to form planar electromagnetic waves. The equipment under test is placed on the rotating bracket, and the vehicle under test is driven to rotate in the planar electromagnetic waves by rotating the rotating bracket, so as to test the antenna of the whole vehicle.

During the test, when the vehicle under test rotates with the rotating bracket, the position of the vehicle under test may be shifted due to inertia, which may lead to the problem of inaccurate test results. Based on the above problems, it is also necessary to set fixing devices on the rotating bracket to fix the position of the vehicle under test, so as to ensure that the position of the vehicle under test does not deviate when rotating. However, adding a fixing device between the vehicle under test and the rotating bracket will also cause the following problems: the fixing device itself will scatter electromagnetic waves, and the electromagnetic waves scattered by the fixing device will also have an impact on the test of the antenna of the whole vehicle, which may lead to inaccurate test results. Therefore, there is an urgent need for a test device that can fix the vehicle under test on the rotating bracket and avoid scattering electromagnetic waves to affect the test results.

### Example 1

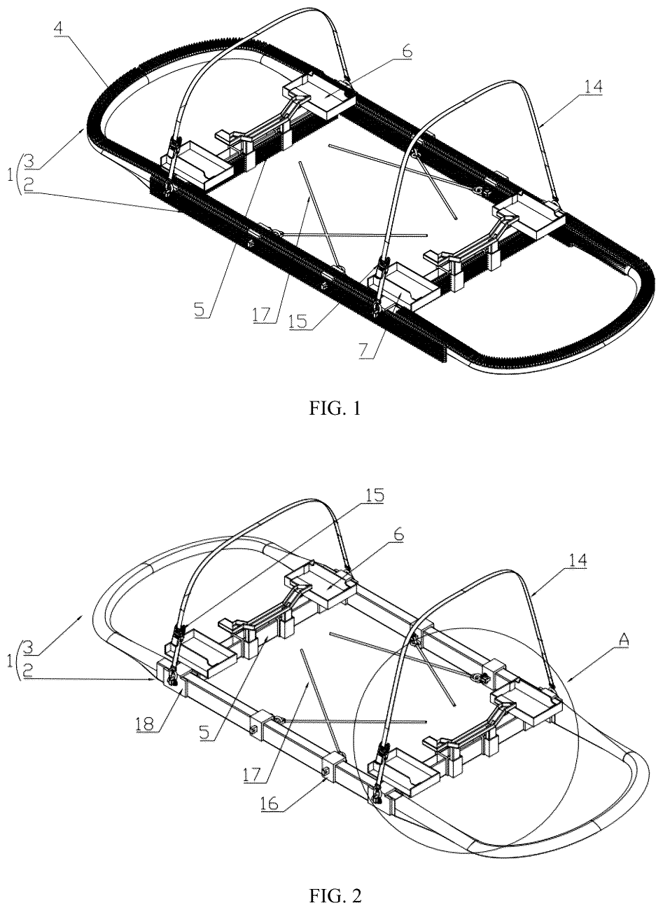

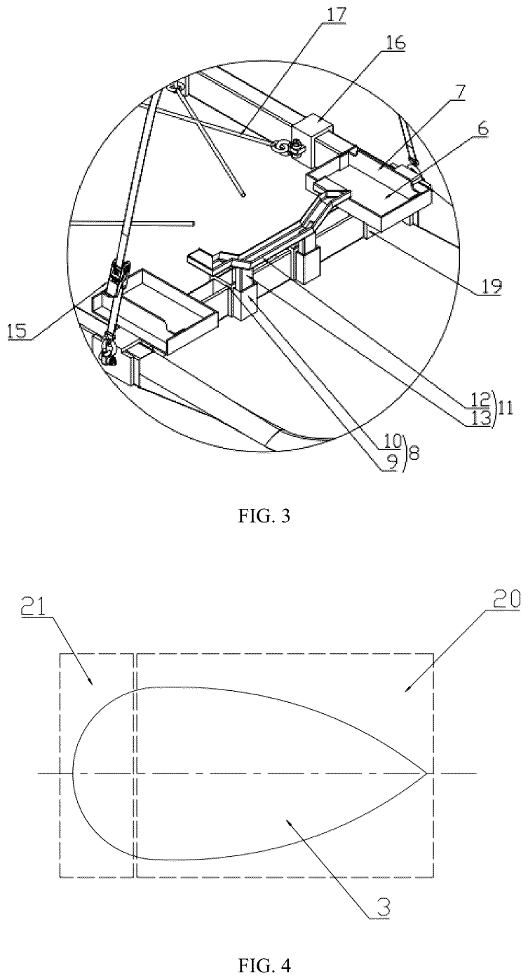

As shown in FIG. 1 and FIG. 3, this example provides a vehicle auxiliary installation fixing device, comprising:
a frame body 1, which comprises a pair of side brackets 2 and a pair of end brackets 3, wherein the pair of side brackets 2 are parallel to each other and both extend along a first direction; the pair of end brackets 3 are arranged along a second direction; and the pair of end brackets 3 are arc-shaped and connected with the same ends of the pair of side brackets 2, and the second direction is perpendicular to the first direction; the frame body 1 is lined with wave-absorbing material 4; and
two groups of fixing components, which are arranged along the first direction, comprising:
a connecting rod 5, wherein the connecting rod 5 extends along the second direction, and both ends of the connecting rod 5 are respectively connected with the pair of side brackets 2; and
a pair of supporting plates 6, which are arranged on the connecting rod 5 along the second direction for supporting a pair of front wheels or a pair of rear wheels of the vehicle under test; the pair of supporting plates 6 are provided with limiting parts 7 for preventing the wheels from moving.

In another example, the connecting rod 5 is slidably connected with the pair of side brackets 2, and the sliding direction is the first direction; the pair of supporting plates 6 is connected with the connecting rod 5 slidably, and the sliding direction is parallel to the second direction.

Specifically, the side brackets 2 are linear steel pipe, and the end brackets 3 are arc steel pipe; the side brackets 2 and the end brackets 3 form an annular closed shape, and the end brackets 3 and the side brackets 2 form the frame body 1 by means of screws and welding. Preferably, the total length of the frame body 1 is within the range of 5.5-6.5 m, and the width is within the range of 1.7-2.5 m. Wherein the arc opening of each end bracket 3 faces one side of the other end bracket 3; the four corners of the frame body 1 and the middle section of the side brackets 2 are provided with holes for connecting with the rotating bracket through screws. Setting the end brackets 3 in an arc shape can reduce the scattering of electromagnetic waves by the frame body 1 in the test environment, which is helpful to improve the accuracy of test results, compared with setting the end brackets 3 in a linear structure like the side brackets 2.

Two groups of the fixing components are arranged in the inner ring of the annular closed shape, respectively corresponding to the front and rear parts of the vehicle under test, and are used for fixing the front and rear parts of the vehicle under test.

The fixing component further comprise a connecting rod 5 and a pair of supporting plates 6. Wherein the connecting rod 5 is arranged perpendicular to the side brackets 2, and both ends of the connecting rod 5 are respectively provided with third sliding seats 18, which are erected on the side brackets 2 and are connected with the side brackets 2 slidably, and the sliding direction is the extending direction of the side brackets 2; By adjusting the relative position between the two connecting rods 5, it can be adapted to different vehicle types. The distance between the two connecting rods 5 is the wheelbases of the vehicle under test. After the connecting rods 5 are adjusted, the third sliding seats 18 and the side brackets 2 are fixed by screws. By arranging the connecting rods 5, by connecting the two side brackets 2 to tighten the two side supports, the structural strength of the whole frame body 1 is enhanced; it is convenient to install the supporting plates 6, and at the same time, it is convenient to adjust the supporting plates 6 along the length direction of the vehicle under test, so as to adapt to vehicles under test with different wheelbase and improve the applicability of the device; Preferably, the width and height of the connecting rods 5 are within the range of 0-0.2 m. On each connecting rod 5, a pair of supporting plates 6 are arranged along the extension direction of the connecting rod 5, and the distance between a pair of supporting plates 6 located on the same connecting rod 5 corresponds to the wheel pitch of the vehicle under test, which is the distance between two wheels on the same axis of the vehicle under test; A fourth sliding seat 19 is fixedly installed at the bottom of the supporting plate 6, and the fourth sliding seat 19 is slidably connected with the connecting rod 5, and the sliding direction is the extending direction of the connecting rod 5; By adjusting the distance between a pair of supporting plates 6, it can be applied to vehicles under test with different wheel pitches. After the pair of supporting plates 6 are adjusted, the fourth sliding seats 19 and the connecting rods 5 are locked by screws. Preferably, the length of the supporting plates 6 should be within the range of 0-0.7 m and the width should be within the range of 0-0.5 m.

The supporting plates 6 is a rectangular flat plate, and three peripheral sides of its top surface are respectively provided with baffles, which are used for limiting the wheel position of the vehicle under test; One side of the top surface of the supporting plates 6 without baffles are provided with the limiting parts 7, and both ends of the limiting parts 7 are respectively connected with two adjacent baffles slidably, and the sliding direction is perpendicular to the extending direction of the limiting parts 7; By adjusting the position of the limiting parts 7, wheels with different widths can be limited, and the applicability of the device is further improved.

As the whole frame body 1 is placed on the rotating bracket for supporting the vehicle under test, the frame body 1 is inevitably placed in the test environment of the vehicle under test. In order to avoid the influence of the scattering of electromagnetic waves in the test environment by the frame body 1 on the test results, besides setting the end brackets 3 into an arc shape, the whole frame body 1 is lined with wave-absorbing material 4, and the reflection of electromagnetic waves by the frame body 1 is reduced through the absorption of electromagnetic waves by the wave-absorbing material 4, thereby reducing the interference of electromagnetic waves scattered by the frame body 1 when the vehicle under test is tested.

The wave-absorbing material 4 is made of ferrite, barium titanate, metal powder, graphite, silicon carbide, conductive fiber, etc.

Preferably, the connecting rods 5 are lined with the wave-absorbing material 4.

Preferably, a plurality of quadrangular cones are formed on the surface of the wave-absorbing material 4 to improve the absorption efficiency of electromagnetic waves.

Further, the section of the pair of end brackets is in the shape of a water drop; the side of the end brackets far from the other end bracket is a drop-shaped tip, and the side of the end brackets close to the other end bracket is a drop-shaped round end.

Specifically, referring to FIG. 4, besides setting the shape of the end brackets 3 as an arc, the front end 20 of the end brackets 3 is pointed, and is the side of the end brackets 3 facing the periphery of the annular closed shape; the rear end 21 is smooth and is the side of the end brackets 3 facing the inner periphery of the annular closed shape; i.e., the cross section of the end brackets 3 is in the shape of a water drop. The cross section of the end brackets 3 is an axisymmetric figure. On one side of the symmetrical axis, the shape of the front end 20 of the end brackets 3 is a curve, and the points on the curve conform to the set curve Formula (I), which is as follows:

$$y = {e}^{( 0.021 * x )} + 0.15 x + 0.0014 * {x}^{2} . \qquad Formula ( I )$$

Where, x represents the horizontal coordinate of a point on the curve, y represents the vertical coordinate of a point on the curve, and e represents the base of the natural logarithm function.

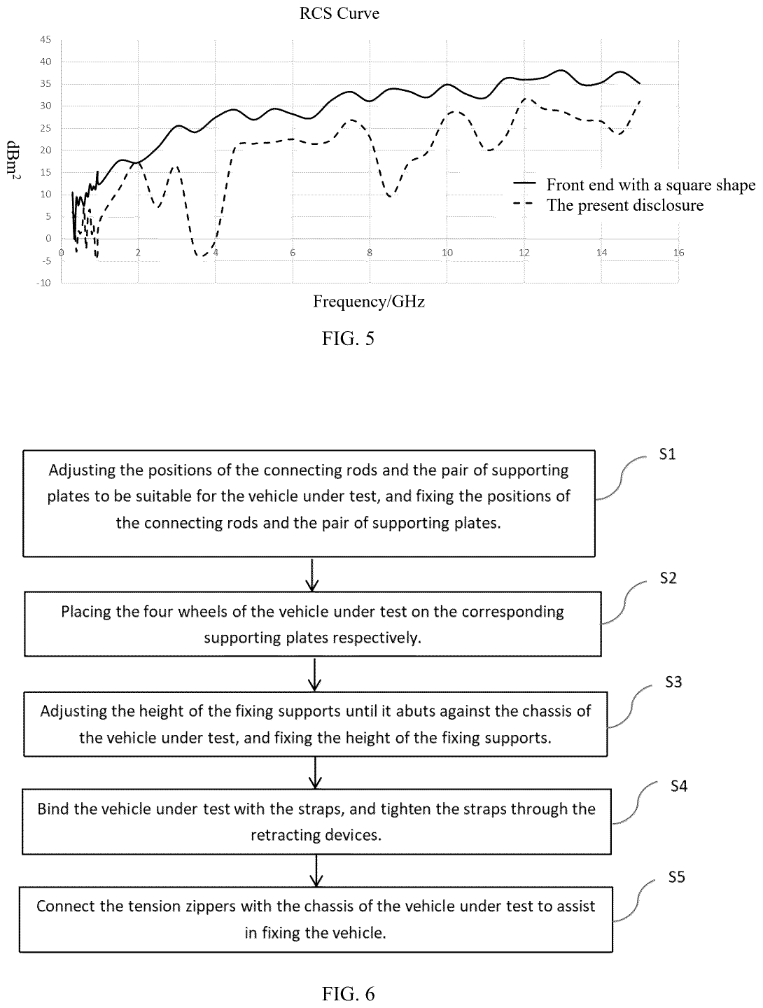

In CST software, the front end 20 of the end brackets 3 is set into a square shape and the front end 20 is a drop shape confirm of the set curve equation, and RCS simulation is carried out. The simulation result is shown in FIG. 5, in which the abscissa is the working frequency and the ordinate is the radar cross section. As shown in FIG. 5, under the condition of the same working frequency, the radar scattering cross section is smaller while the cross section of the end brackets 3 is set to a water drop shape, which means that the scattered electromagnetic waves are less.

Further, an angle of a tip of the water drop shape is between 70° and 85°.

Preferably, the angle of the front end 20 of the end brackets 3 is set between 70° and 85° to further improve the scattering of electromagnetic waves.

Further, the fixing component further comprising:
a first sliding seat 8 arranged between the pair of supporting plates 6; the first slide seat 8 comprises a sliding part 9 and an installation part 10 arranged at one side of the sliding part 9, wherein the sliding part 9 is connected with the connecting rods 5 slidably, and the sliding direction is the second direction; and
a fixing support 11, which comprises a supporting part 12 and a connecting part 13; the connecting part 13 is connected with the installation part 10 slidably, and the sliding direction is a third direction which is perpendicular to the first direction and the second direction; the supporting part 12 is arranged at one end of the connecting part 13 far away from the connecting rods 5.

Specifically, the first sliding seat 8 is erected on the connecting rods 5 through the sliding part 9, and can slide along the extending direction of the connecting rods 5; the installation part 10 is arranged on the side wall of the sliding part 9, and the installation part 10 is provided with a groove with an upward opening. The connecting part 13 of the fixing support 11 extends into the groove on the installation part 10 and can slide in the vertical direction; the supporting part 12 is fixedly installed at the top end of the connecting part 13, and is arranged in parallel with the connecting rods 5. Both ends of the supporting part 12 are bent upwards to support the chassis of the vehicle under test. Sliding the sliding part 9 to adjust the position of the supporting part 12 along the extension direction of the connecting rods 5, and after adjustment, the sliding part 9 and the connecting rods 5 are locked by screws; the position of the supporting part 12 in the vertical direction can be adjusted by sliding the connecting part 13, and the connecting part 13 and the installation part 10 are locked by screws after adjustment. Because the position of the supporting part 12 is adjustable, it can be applied to various vehicles under test with different chassis structures, and the applicability of the vehicle auxiliary installation fixing device is improved.

Further, the fixing component further comprising:
a strap 14, two ends of which are respectively connected with two ends of the connecting rods 5; and
a retracting device 15 arranged at one end of the strap 14 for adjusting the tightness of the strap 14.

Specifically, both ends of the strap 14 are hooked on the third sliding seats 18 on the corresponding side by hooks, and the hooking structure makes it convenient to disassemble the strap 14, so as to facilitate replacement when the strap 14 are broken or the length doesn't meet requirements; When all four wheels of the vehicle under test are placed on the supporting plates 6, the vehicle under test is bound by the strap 14 to auxiliary fix the vehicle under test. In view of the different shapes of different vehicles under test, in order to reduce the number of times of replacing the strap 14, the retracting devices 15 are installed at the ends of the strap 14. By passing the strap 14 through the retracting devices 15, the length of the strap 14 can be adjusted by the retracting function of the retracting devices 15, so as to facilitate the binding and fixing of vehicles under test with different shapes. The retracting devices 15 retract both ends of the strap 14 that passed through the retracting devices 15 to change the length of the strap 14. The retracting devices 15 are a rope retracting device in the prior art.

Further, a plurality of groups of tensioning assemblies are further arranged between the two groups of fixing components, and the tensioning assembly comprises:
a second sliding seat 16, which is slidably installed on the pair of side brackets 2, and the sliding direction is the first direction; the position of the second sliding seat 16 can be fixed after sliding; and
a tension zipper 17, one end of which is connected with the second sliding seat 16, and the other end of which is used for connecting with the chassis of the vehicle under test.

Specifically, the second sliding seats 16 are erected on the side brackets 2 slidably. After the positions of the second sliding seats 16 are adjusted, the second sliding seats 16 are fixed on the side brackets 2 by screws. When all four wheels of the vehicle under test are placed on the supporting plates 6, the free ends of the tension zippers 17 are connected to the chassis of the vehicle under test, and the tension zippers 17 are tensioned by adjusting the position of the second sliding seats 16, so that the vehicle under test is further fixed by the tension zippers 17, and the vehicle under test is prevented from moving in the rotation process; Preferably, the diameter of the tension zippers 17 is within the range of 0.01-0.03 mm, and the length of the tension zippers 17 is within the range of 1.3-1.6 m.

### Example 2

Please refer to FIG. 6. This example provides a vehicle auxiliary installation fixing method, which is suitable for the vehicle auxiliary installation fixing device, wherein comprising the following steps:
S1. adjusting the positions of the connecting rods 5 and the pair of supporting plates 6 to be suitable for the vehicle under test, and fixing the positions of the connecting rods 5 and the pair of supporting plates 6;
S2. placing the four wheels of the vehicle under test on the corresponding supporting plates 6 respectively;
S3. adjusting the height of the fixing supports 11 until it abuts against the chassis of the vehicle under test, and fixing the height of the fixing supports 11;
S4. bind the vehicle under test with the strap 14, and tighten the strap 14 through the retracting devices 15;
S5. connect the tension zippers 17 with the chassis of the vehicle under test to assist in fixing the vehicle.

The method provided by this example is as follows: firstly, the frame body 1 is mounted on the rotating bracket by screws; After the position of the frame body 1 is fixed, the distance between the two connecting rods 5 is adjusted of the wheelbase of the vehicle under test, and after the adjustment, the third sliding seats 18 and the side brackets 2 are locked by screws; After the position of the connecting rods 5 is adjusted, the distance between the pair of supporting plates 6 is adjusted according to the wheel distance of the vehicle under test, and after the adjustment, the fourth sliding seat 19 is locked with the connecting rods 5 by screws; After the position of the supporting plates 6 is adjusted, the vehicle under test is placed above the frame body 1, and four wheels of the vehicle under test are respectively placed on the corresponding supporting plates 6; After the wheel is placed on the corresponding supporting plates 6, the positions of the limiting parts 7 are adjusted to limit the positions of the wheels, and after the adjustment, the limiting parts 7 are locked with the baffle by screws; After the limiting parts 7 are locked, the strap 14 are tied to the body of the vehicle under test, and the strap 14 are tightened by the retracting devices 15. After the strap 14 is tightened, the free ends of the tension zippers 17 are fixed on the chassis of the vehicle under test, the positions of the second sliding seats 16 are adjusted to tension the tension zippers 17, and after the positions of the second sliding seats 16 are adjusted, the second sliding seats 16 are locked with the side brackets 2, and the vehicle under test is fixed.

Through the method provided by this example, the vehicle under test can be fixed on the rotating bracket, so as to prevent the vehicle under test from moving due to the rotation of the rotating bracket in the test process and avoid the problem of inaccurate test results due to the movement of the vehicle.

The above description is only the preferred example of the present disclosure and an explanation of the applied technical principles. It should be understood by those skilled in the art that the scope of the present disclosure involved in the present disclosure is not limited to the technical scheme formed by the specific combination of the above technical features, but also covers other technical schemes formed by any combination of the above technical features or their equivalent features without departing from the inventive concept. For example, the above features are replaced with (but not limited to) technical features with similar functions disclosed in the present disclosure.

1. A vehicle auxiliary installation fixing device, comprising:
a frame body, comprising a pair of side brackets and a pair of end brackets, wherein the pair of side brackets are parallel to each other and both extend along a first direction;
and the pair of end brackets are arranged along a second direction; and the pair of end brackets are arc-shaped and connected with same ends of the pair of side brackets, and the second direction is perpendicular to the first direction; and the frame body is lined with wave-absorbing material; and
two groups of fixing components, which are arranged along the first direction, wherein the fixing component comprising:
a connecting rod, wherein the connecting rod extends along the second direction, and both ends of the connecting rod are respectively connected with the pair of side brackets; and
a pair of supporting plates, which are arranged on the connecting rod along the second direction for supporting a pair of front wheels or a pair of rear wheels of a vehicle under test; and the pair of supporting plates are provided with limiting parts for preventing wheels from moving; and
a section of the pair of end brackets is in the shape of a water drop; and a side of the end brackets far from another end bracket is a drop-shaped tip, and the side of the end brackets close to another end bracket is a drop-shaped round end.

2. The vehicle auxiliary installation fixing device of claim 1, wherein the connecting rod is slidably connected with the pair of side brackets, and a sliding direction is the first direction; and the pair of supporting plates is connected with the connecting rod slidably, and the sliding direction is parallel to the second direction.

3. The vehicle auxiliary installation fixing device of claim 2, wherein the fixing component further comprising:
a first sliding seat, arranged between the pair of supporting plates; and the first slide seat comprises a sliding part and an installation part arranged at one side of the sliding part, wherein the sliding part is connected with the connecting rod slidably, and the sliding direction is the second direction; and
a fixing support, which comprises a supporting part and a connecting part; and the connecting part is connected with the installation part slidably, and the sliding direction is a third direction which is perpendicular to the first direction and the second direction;
and the supporting part is arranged at one end of the connecting part far away from the connecting rod.

4. The vehicle auxiliary installation fixing device of claim 3, wherein both ends of the supporting part are bent in a direction away from the connecting part.

5. The vehicle auxiliary installation fixing device of claim 4, wherein the fixing component further comprising:
a strap, two ends of which are respectively connected with two ends of the connecting rod; and
a retracting device, arranged at one end of the strap for adjusting tightness of the strap.

6. The vehicle auxiliary installation fixing device of claim 5, wherein a plurality of groups of tensioning assemblies are further arranged between the two groups of fixing components, and the tensioning assembly comprises:
a second sliding seat, which is slidably installed on the pair of side brackets, and the sliding direction is the first direction; position of the second sliding seat can be fixed after sliding; and
a tension zipper, one end of which is connected with the second sliding seat, and another end of which is used for connecting with a chassis of the vehicle under test.

7. The vehicle auxiliary installation fixing device of claim 6, wherein an angle of a tip of the water drop shape is between 70° and 85°.

8. The vehicle auxiliary installation fixing device of claim 7, wherein the connecting rod is lined with the wave-absorbing material.

9. A vehicle auxiliary installation fixing method of claim 8, which is suitable for the vehicle auxiliary installation fixing device, comprising following steps:
adjusting positions of the connecting rod and the pair of supporting plates to be suitable for the vehicle under test, and fixing the positions of the connecting rod and the pair of supporting plates; and
placing four wheels of the vehicle under test on corresponding supporting plates respectively; and
adjusting height of the fixing supports until it abuts against the chassis of the vehicle under test, and fixing the height of the fixing supports; and
binding the vehicle under test with the strap, and tighten the strap through retracting devices; and
connecting the tension zipper with the chassis of the vehicle under test to assist in fixing the vehicle.
